(19) United States
(12) Patent Application Publication
(10) Pub. No.: US 2009/0261364 A1
(43) Pub. Date: Oct. 22, 2009

(54) Fluorescent substance

(76) Inventors: Kyota Ueda, Yokohama-shi (JP); Kenji Kohiro, Tsukuba-shi (JP); Yoshihiko Tsuchida, Tsukuba-shi (JP)

Correspondence Address: FITCH, EVEN, TABIN & FLANNERY, P. O. BOX 18415, WASHINGTON, DC, 20036, US

(21) Appl. No.: 11/661,293

(22) PCT Filed: Aug. 30, 2005
(86) PCT No.: PCT/JP05/16190

§ 371 Date: Feb. 27, 2007

(30) Foreign Application Priority Data
Aug. 31, 2004 (JP) 2004-251727
Dec. 27, 2004 (JP) 2004-375931

(51) Int. Cl. H01L 33/00; C09K 11/77

(52) U.S. Cl. 257/98; 252/301.4 R; 257/13; 257/E33.061

(57) ABSTRACT

A fluorescent substance characterized by comprising a base crystal composed of a compound represented by the formula: M¹ₐM²_{b}N_{c} wherein M¹ is at least one element selected from the group consisting of Mg, Ca, Sr, Ba and Zn; M² is at least one element selected from the group consisting of Al, Ga and In; and c=(2a/3)+b, 0<a and 0<b, with at least one element selected from the group consisting of a rare earth metal, Zn and Mn as an activator contained therein.

### TECHNICAL FIELD

The present invention relates to a fluorescent substance.

### BACKGROUND ART

Fluorescent substances are used for various light emitting devices, for example, a visible-light-excited light emitting device such as a white LED composed of an LED that emits blue light and a fluorescent substance in combination, a near ultraviolet- to violet-light-excited light emitting device composed of an LED that emits near ultraviolet to violet light and a fluorescent substance in combination, an ultraviolet-excited light emitting device such as a back light for liquid crystal and a fluorescent lamp, a vacuum-ultraviolet-excited light emitting device such as a plasma display panel and a noble gas lamp, an electron-beam-excited light emitting device such as a cathode-ray tube and FED (Field Emission Display), an X-ray-excited light emitting device such as an X-ray imaging device, and an electric-field-excited light emitting device such as an inorganic EL display.

As a near ultraviolet- to violet-light-excited light emitting device composed of an LED that emits near ultraviolet to violet light and a fluorescent substance in combination, for example, there is proposed a light emitting device that emits light in various colors (e.g., see Patent Document 1) in which a fluorescent substance that can be excited by light emitted from an LED and change wavelength is disposed on a light emitting surface of the LED that emits near ultraviolet to violet light, or a white light emitting device that emits light visibly in white color (e.g., see Patent Document 2).

Fluorescent substances used in these light emitting devices, such as Y₂O₃: Eu for a red fluorescent substance, Zn_{0.6}Cd_{0.4}S:Ag for a green fluorescent substance, (Sr, Ca)₁₀(PO₄)₆Cl₂: Eu for a blue fluorescent substance, Y₃Al₅O₁₂:Ce (e.g., see Patent Document 1) and Eu_{0.5}Si_{9.75}Al_{2.25}N_{15.25}O_{0.75}, which is an α-sialon activated with Eu, for yellow fluorescent substances, and the like are proposed, but none of them has a sufficient brightness; a fluorescent substance which can be excited by near ultraviolet to blue light and exhibits a high brightness has been desired.
[Patent Document 1] JP-A-09-153645
[Patent Document 2] JP-A-2002-363554

The present invention is to solve the above described problems and has an object to provide a fluorescent substance that can be excited by near ultraviolet to blue light and exhibits a high brightness.

### DISCLOSURE OF THE INVENTION

The present inventors have extensively studied to solve the above described problems and have found that a fluorescent substance which uses a compound composed of a nitride of a group II element and a group III-B element, a compound composed of a nitride of a group II element and a group IV-B element, or a compound composed of a nitride of a group II element, a group III-B element and a group IV-B element as the base crystal, with an activator contained therein, is excited by near ultraviolet to blue light and exhibits a high brightness. The present inventors thus have achieved the present invention.

That is, the present invention provides a fluorescent substance characterized by comprising a base crystal composed of a compound represented by the formula: M¹ₐM²_{b}N_{c}, wherein M¹ is at least one element selected from the group consisting of Mg, Ca, Sr, Ba and Zn; M² is at least one element selected from the group consisting of Al, Ga and In; and c=(2a/3)+b, 0<a and 0<b, with at least one element selected from the group consisting of a rare earth metal, Zn and Mn as an activator contained therein.

The present invention also provides a fluorescent substance characterized by comprising a base crystal composed of a compound represented by the formula: M³_{d}M⁴ₑN_{f}, wherein M³ is at least one element selected from the group consisting of Mg, Ca, Sr, Ba and Zn; M⁴ is at least one element selected from the group consisting of Ge, Sn and Pb; and f=(2d/3)+(4e/3), 0<d and 0<e, with at least one element selected from the group consisting of a rare earth metal, Zn and Mn as an activator contained therein.

The present invention alternatively provides a fluorescent substance characterized by comprising a base crystal composed of a compound represented by the formula: M⁵_{g}M⁶ₕM⁷ⱼNₖ, wherein M⁵ is at least one element selected from the group consisting of Mg, Ca, Sr, Ba and Zn; M⁶ is at least one element selected from the group consisting of Al, Ga and In; M⁷ is at least one element selected from the group consisting of Ge, Sn and Pb; and k=(2g/3)+h+(4j/3), 0<g, 0<h and 0<j, with at least one element selected from the group consisting of a rare earth metal, Zn and Mn as an activator contained therewith.

The fluorescent substance of the present invention is effectively excited by the light in a wavelength range of near ultraviolet to blue emitted by a group III-V compound semiconductor light emitting element, and can be made into a light emitting element having a high brightness in combination with a near ultraviolet to blue light emitting element, and also made into a white LED that emits a purer white light than conventional light emitting elements, thus leading to the present invention being industrially highly useful.

### BRIEF DESCRIPTION OF THE DRAWINGS

FIG. 1 shows a metal organic vapor phase epitaxial semiconductor manufacturing apparatus.

FIG. 2 shows a molecular beam epitaxy vapor phase epitaxial semiconductor manufacturing apparatus.

Numeral references are as follows:
9: vacuum reaction furnace
10: susceptor
11: growth substrate
12: ion gauge
13: ultrahigh vacuum pump
14: ammonia supply conduit
15-18: K cell

FIG. 3 shows a light emitting property of a CaₐGa_{b}N_{c}-based fluorescent substance film manufactured by molecular beam epitaxy.

FIG. 4 shows a comparison in light emitting property between a GaN-based fluorescent substance film and a CaₐGa_{b}N_{c}-based fluorescent substance film manufactured by molecular beam epitaxy.

FIG. 5 shows a light emitting property of a GaN-based fluorescent substance film manufactured by molecular beam epitaxy.

FIG. 6 shows a light emitting property of a fluorescent substance film manufactured by implanting Ca, using an ion implantation method, into a GaN-based fluorescent substance film manufactured by molecular beam epitaxy, followed by annealing in ammonia.

FIG. 7 shows a light emitting property of a ZnGeN₂-based fluorescent substance film manufactured by metal organic vapor phase epitaxy.

FIG. 8 shows a light emitting property of CaₐGa_{b}N_{c}-based fluorescent substance powder manufactured by a high temperature calcination method under an ammonia atmosphere.

### BEST MODE FOR CARRYING OUT THE INVENTION

The first fluorescent substance of the present invention is characterized by comprising a base crystal composed of a compound represented by the formula (1):

M¹ₐM²_{b}N_{c} (1)

with at least one element selected from the group consisting of a rare earth metal, Zn and Mn as an activator contained therein. This fluorescent substance can be excited by the light in a wavelength range of near ultraviolet to blue, and made into a fluorescent substance exhibiting a high brightness.

M₁ is a group II metal element, and includes at least one element selected from the group consisting of Mg, Ca, Sr, Ba and Zn, preferably at least one element selected from the group consisting of Ca, Sr and Ba. M² is a group III-B metal element, and includes at least one element selected from the group consisting of Al, Ga and In, preferably at least one element selected from the group consisting of Ga and In, more preferably Ga.

The relation among a, b and c in the formula (1) is given by c=(2a/3)+b, and 0<a and 0<b. The molar ratio of M¹ to M², a/b, is preferably not less than 0.001 and not more than 20, more preferably not less than 0.2 and not more than 5, most preferably 1.5.

An activator of the first fluorescent substance of the present invention is at least one element selected from the group consisting of a rare earth metal element, Zn and Mn, preferably at least one element selected from the group consisting of Ce, Pr, Nd, Pm, Sm, Eu, Tb, Dy, Ho, Er, Tm, Yb and Mn, more preferably at least one element selected from the group consisting of Ce, Sm, Eu, Tb, Yb and Mn. Note that the rare earth metal elements in the present invention does not include Sc.

The content of the activator in the first fluorescent substance of the present invention is preferably in a range of not less than 0.00001 and not more than 0.3 , more preferably in a range of not less than 0.0001 and not more than 0.1, further preferably in a range of not less than 0.0005 and not more than 0.05, based on the molar sum of M¹ and M², a+b, in the formula (1).

In the above described preferable embodiments, provided that M¹ is M²¹ which is at least one element selected from the group consisting of Ca, Sr and Ba; M² is M²² which is at least one element selected from the group consisting of Ga and In; an activator L²¹ is at least one element selected from the group consisting of Ce, Sm, Eu, Tb, Yb and Mn; 0<a and 0<b, and a/b is in a range of not less than 0.2 and not more than 5; and the content, x, of the activator is in a range of not less than 0.0001×(a+b) and not more than 0.1×(a+b), a fluorescent substance composed of a compound represented by the formula (2) below is preferable. Here, letting “u” be a molar number of divalent L²¹, it follows that trivalent L²¹ is (1−u) mol, so p=(2u/3)+(1−u).

M²¹ₐM²²_{b}N_{c}19 xL²¹Nₚ (2)

Further, provided that M²¹ is at least one element selected from the group consisting of Ca, and Sr; M²² is Ga; an activator L is at least one element selected from the group consisting of Ce, Sm, Eu, Yb and Mn; 0<a and 0<b, and a/b is in a range of not less than 0.2 and not more than 5; and x is in a range of not less than 0.0005×(a+b) and not more than 0.01×(a+b), (here, letting “u” be a molar number of divalent L²¹, it follows that trivalent L²¹ is (1−u) mol, so p=(2u/3)+(1−u)), a fluorescent substance composed of a compound represented by the formula (2) above is more preferable.

The second fluorescent substance of the present invention is characterized in that a base crystal composed of a compound represented by the formula (3):

M³_{d}M⁴ₑN_{f} (3)

contains as an activator at least one element selected from the group consisting of a rare earth metal, Zn and Mn. This fluorescent substance is excited by the light in the wavelength range of near ultraviolet to blue and exhibits a high brightness.

M³ is a group II metal element, and includes at least one element selected from the group consisting of Mg, Ca, Sr, Ba and Zn, preferably at least one element selected from the group consisting of Ca, Sr, Ba and Zn. M⁴ is a group IV-B metal element, and includes at least one element selected from the group consisting of Ge, Sn and Pb, preferably at least one element selected from the group consisting of Ge and Sn, most preferably Ge.

The relation between d, e and f in the above described formula (3) is given by f=(2d/3)+4e/3), and 0<d and 0<e. The molar ratio of M³ to M⁴, d/e, is preferably not less than 0.05 and not more than 20, more preferably not less than 0.2 and not more than 5, most preferably 1.

The activator of the second fluorescent substance of the present invention is similar to that of the above described first fluorescent substance; the content of the activator in the second fluorescent substance of the present invention is preferably in a range of not less than 0.00001 and not more than 0.3, more preferably not less than 0.0001 and not more than 0.1, further preferably not less than 0.0005 and not more than 0.05, based on the molar sum of M³ and M⁴, d+e, in the formula (3).

In the above described preferable embodiments of the second fluorescent substance of the present invention, provided that M³ is M²³ which is at least one element selected from the group consisting of Ca, Sr, Ba and Zn; M⁴ is M²⁴ which is at least one element selected from the group consisting of Ge and Sn; an activator L²² is at least one element selected from the group consisting of Ce, Sm, Eu, Tb, Yb and Mn; 0<d and 0<e, and d/e is in a range of not less than 0.2 and not more than 5; and the content, y, of the activator is in a range of not less than 0.0001×(d+e) and not more than 0.1×(d+e), a fluorescent substance composed of a compound represented by the formula (4) below is preferable. Here, letting “v” be a molar number of divalent L²², it follows that trivalent L²² is (1−v) mol, so q=(2v/3)+(1−v).

M²³_{d}M²⁴ₑN_{f}·yL²²N_{q} (4)

Further, provided that M²³ is at least one element selected from the group consisting of Ca, Sr and Zn; M²⁴ is Ge; an activator L²² is at least one element selected from the group consisting of Ce, Sm, Eu, Yb and Mn; 0<d and 0<e, and d/e is in a range of not less than 0.2 and not more than 5; and y is in a range of not less than 0.0005×(d+e) and not more than 0.01×(d+e), (here, letting “v” be a molar number of divalent L²², it follows that trivalent L²² is (1−v) mol, so q=(2v/3)+(1−v)), a fluorescent substance composed of a compound represented by the formula (4) above is more preferable.

The third fluorescent substance of the present invention is characterized in that a base crystal composed of a compound represented by the formula (5):

M⁵_{g}M⁶ₕM⁷ⱼNₖ (5)

contains as an activator at least one element selected from the group consisting of a rare earth metal, Zn and Mn. This fluorescent substance is excited by the light in the wavelength range of near ultraviolet to blue, and exhibits a high brightness.

M⁵ is a group II metal element, and includes at least one element selected from the group consisting of Mg, Ca, Sr, Ba and Zn, preferably at least one element selected from the group consisting of Ca, Sr, Ba and Zn. M⁶ is a group III-B metal element, and includes at least one element selected from the group consisting of Al, Ga and In, preferably at least one element selected from the group consisting of Ga and In, further preferably Ga. M⁷ is a group IV-B metal element, and includes at least one element selected from the group consisting of Ge, Sn and Pb, more preferably at least one element selected from the group consisting of Ge and Sn, further preferably Ge.

The relation between g, h, j and k in the above described formula (5) is given by k=(2g/3)+h+(4j/3), and 0<g, 0<h and 0<j. The molar ratio of M⁵ to M⁷, g/j, is preferably not less than 0.05 and not more than 20, more preferably not less than 0.2 and not more than 5; and the molar ratio of M⁶ to M⁷, h/j, is preferably not less than 0.05 and not more than 20, more preferably not less than 0.2 and not more than 5.

The activator of the third fluorescent substance of the present invention is similar to that of the above described first fluorescent substance; the content of the activator in the third fluorescent substance of the present invention is preferably in a range of not less than 0.00001 and not more than 0.3 , more preferably not less than 0.0001 and not more than 0.1, further preferably not less than 0.0005 and not more than 0.05, based on the molar sum of M⁵, M⁶ and M⁷, g+h+j, in the formula (5).

In the above described preferable embodiments of the third fluorescent substance of the present invention, provided that M⁵ is M²⁵ which is at least one element selected from the group consisting of Ca, Sr, Ba and Zn; M⁶ is M²⁶ which is at least one element selected from the group consisting of Ga and In; M⁷ is M²⁷ which is at least one element selected from the group consisting of Ge and Sn; an activator L²³ is at least one element selected from the group consisting of Ce, Sm, Eu, Tb, Yb and Mn; 0<g, 0<h and 0<j, and g/j is in a range of not less than 0.2 and not more than 5, and h/j is in a range of not less than 0.2 and not more than 5; and the content, z, of the activator is in a range of not less than 0.0001×(g+h+j) and not more than 0.1×(g+h+j), a fluorescent substance composed of a compound represented by the formula (6) below is preferable. Here, letting “w” be a molar number of divalent L²³, it follows that trivalent L²³ is (1−w) mol, so r=(2w/3)+(1−w).

M²⁵_{g}M²⁶ₕM²⁷ⱼNₖ·zL²³Nᵣ (6)

Further, provided that M²⁵ is at least one element selected from the group consisting of Ca, Sr and Zn; M²⁶ is Ga; M²⁷ is Ge; an activator L²³ is at least one element selected from the group consisting of Ce, Sm, Eu, Yb and Mn; 0<g, 0<h and 0<j, and g/j is in a range of not less than 0.2 and not more than 5, and h/j is in a range of not less than 0.2 and not more than 5, and z is in a range of not less than 0.0005×(g+h+j) and not more than 0.01×(g+h+j) (here, letting “w” be a molar number of divalent L²³, it follows that trivalent L²³ is (1−w) mol, so r=(2w/3)+(1−w)), a fluorescent substance composed of a compound represented by the formula (6) above is more preferable.

Then, as long as the first to third fluorescent substances are substantially a nitride, they may contain approximately 2 wt. % of oxygen, which is an amount regarded as impurities.

Of such first to third fluorescent substances of the present invention, a fluorescent substance having an excitation spectrum peak between 390 nm and 480 nm, which is effectively excited by near ultraviolet to blue light and exhibits a high brightness, and a fluorescent substance having an excitation spectrum peak between 390 nm and 420 nm, which is effectively excited by near ultraviolet to violet and exhibits a high brightness, are preferable. Particularly, they are made into light emitting devices exhibiting a high brightness especially in combination with an LED composed of a nitride semiconductor that emits light in the wavelength of near ultraviolet to blue.

Hereinafter, methods of manufacturing the fluorescent substance of the present invention will be illustrated.

The methods of manufacturing nitride fluorescent substances relevant to the present invention include a method by reacting group II and III metals, group II and IV metals, or group II, III and IV metals with a gaseous or liquid compound containing a nitrogen atom such as ammonia, a method by sintering nitrides of group II and III metals, nitrides of group II and IV metals, or nitrides of group II, III and IV metals under a nitrogen atmosphere at a high pressure and a high temperature, metal organic vapor phase epitaxy (hereinafter referred to as “MOVPE” in some cases), molecular beam epitaxy (hereinafter referred to as “MBE” in some cases), and hydride vapor phase epitaxy (hereinafter referred to as “HVPE” in some cases).

Of these, MOVPE, which is one of preferable methods of manufacturing the fluorescent substance of the present invention, will be specifically illustrated.

In MOVPE, as in the method of manufacturing LEDs (see JP-A-07-249795 and JP-A-09-116130, for example), an organic metal gas is made to react and grow fluorescent substance crystals on a growth substrate.

The growth substrate includes one such as sapphire, SiC or Si. The above described growth substrate is heated, and a nitrogen raw gas and raw gases for Ga, Al, In, Ge, Sn, Pb, Mg, Ca, Sr, Ba, Zn and an element of an activator, respectively, are made to flow, react and grow fluorescent substance crystals thereon.

As a Ga raw gas, an aluminum raw gas and an indium raw gas, a trialkyl compound or a trihydride with alkyl groups having one to three carbon atoms bonded or with hydrogen atoms bonded to each metal atom bonded commonly used. As a Ga raw material, for example, trimethylgallium ((CH₃)₃Ga), triethylgallium ((C₂H₅)₃Ga), etc. can be used.

An activator is added to base crystals by mixing the above described starting raw gas with a gaseous compound containing at least one element selected from the group consisting of a rare earth metal, Zn and Mn. The activator is at least one element selected from the group consisting of a rare earth metal, Zn and Mn, preferably at least one element selected from the group consisting of Ce, Pr, Nd, Pm, Sm, Eu, Tb, Dy, Ho, Er, Tm, Yb and Mn, more preferably at least one element selected from the group consisting of Ce, Sm, Eu, Tb, Yb and Mn. In the case of the metal organic vapor phase epitaxy, an organic metal compound of a rare earth metal is used as the raw material. Organic metal groups include a trimethyl group, a triethyl group, a biscyclopentadienyl group, a bismethylcyclopentadienyl group and a bisethylcyclopentadienyl group.

Commonly used as a nitrogen raw material is ammonia, and also used are hydrazine, methylhydrazine, 1,1-dimethylhydrazine, 1,2-dimethylhydrazine, t-butylamine, ethylenediamine and the like. These can be used alone or as a mixture in optional combination. Of these raw materials, ammonia and hydrazine are preferable with less contamination of semiconductors with carbon because they contain no carbon atoms in the molecule.

As an atmospheric gas at growth time and a carrier gas for an organic metal raw material, nitrogen, hydrogen, argon, helium, etc. can be used alone or as a mixture thereof. Hydrogen gas or helium gas is more preferable since the predecomposition of the raw material is suppressed in the atmosphere.

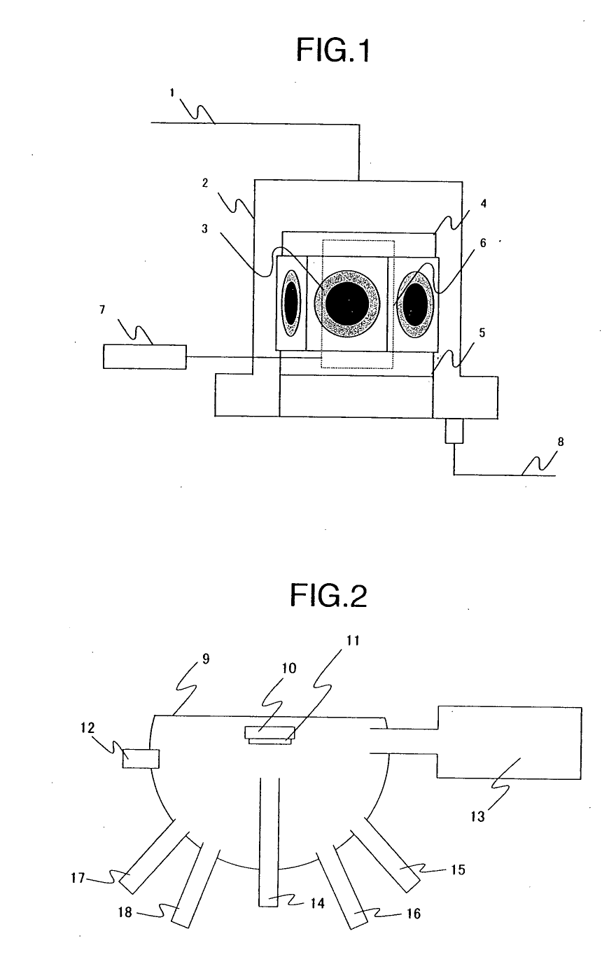

An illustrative diagram of an example of a vapor phase growth semiconductor manufacturing apparatus used in the manufacture by MOVPE is shown in FIG. 1. The vapor phase growth semiconductor manufacturing apparatus is equipped with a reaction furnace 2 to which raw gases are supplied from a raw material supply unit (not shown in FIG. 1) through a raw material supply line 1. A susceptor 4 is provided to heat growth substrates 3 in the reaction furnace 2. The susceptor 4 is a polygonal column; a plurality of the substrates 3 are mounted on the surface thereof. The susceptor 4 has a structure rotatable by a rotation device 5. The susceptor 4 is equipped inside with an infrared-ray lamp 6 to heat the susceptor 4. The substrates 3 can be heated to a desired growth temperature by flowing an electric current for heating from a heating power source 7 to the infrared-ray lamp 6. By this heating, the raw gases supplied through the raw material supply line 1 to the reaction furnace 2 are designed to be thermally decomposed on the substrates 3 and have a desired compound vapor-deposited on the substrates 3. The unreacted raw gases of the raw gases supplied to the reaction furnace 2 are discharged from a discharge port 8 outside the reaction furnace and sent to a discharged gas disposed unit.

The fluorescent substance crystals grown on the substrates in such a way may be used as powder obtained by shaving the fluorescent substance crystal film off the substrates; and in the case where they are disposed on the light emitting surface of LEDs (hereinafter referred to simply as “light emitting element” in some cases) composed of a nitride semiconductor, a planar fluorescent substance film obtained by peeling the fluorescent substance film off the substrates can be also affixed on the light emitting surface of the light emitting elements. Besides, in manufacturing LEDs by MOVPE or MBE, after a requisite compound semiconductor layer is laminated, the fluorescent substance layer of the present invention may be successively grown. Alternatively, powder of the fluorescent substance of the present invention can be deposited on light emitting elements by means such as laser ablation, magnetron sputtering or plasma CVD.

The fluorescent substance of the present invention may be used alone, but a plurality of the fluorescent substances of the present invention emitting different colors of light may be used in combination and disposed on the light emitting surface of light emitting elements to make light emitting devices. Light emitting colors of fluorescent substances can be adjusted in combination of, for example, blue and yellow, red and green, and red, green and blue. In particular, a white light emitting device using a nitride semiconductor can be made by using an LED composed of a nitride semiconductor that emits light of a wavelength of near ultraviolet to blue and the fluorescent substance of the present invention, wherein the amount of the fluorescent substance is adjusted such that the light in a mixed light emitting color becomes visibly white and is disposed on the light emitting surface of the light emitting elements as described above. The white light emitting device using the fluorescent substance of the present invention, thus obtained, makes a high brightness one.

The white light emitting device of the present invention can be manufactured by using powder of the fluorescent substance of the present invention by conventional methods (see JP-A-05-152609 and JP-A-07-99345, for example). That is, the fluorescent substance of the present invention is dispersed in a light transmissive resin such as an epoxide resin, a polycarbonate or a silicone rubber. The fluorescent substance-dispersed resin is molded so as to surround light emitting elements (nitride semiconductor) on a stem, whereby a white light emitting device can be manufactured.

Now, specific examples of light emitting elements that emit near ultraviolet to blue light for exciting a fluorescent substance will be illustrated. The light emitting element has basically the structure in which an n-type compound semiconductor crystal layer, a light emitting layer composed of a compound semiconductor crystal and a p-type compound semiconductor crystal layer are laminated on a substrate. Arranging the light emitting layer between the n-type layer and the p-type layer can make light emitting elements with a low driving voltage and a high efficiency. Between the n-type layer and the light emitting layer, and between the light emitting layer and the p-type layer, several layers different in compositions, electric conductivity and doping concentrations may be optionally inserted. For example, a laminate of at least two layers different in composition from each other, represented by the general formula: InₓGa_{y}Al_{z}N (0≦X≦1, 0≦Y≦, 0≦Z<1, X+Y+Z=1), may be introduced. The layers may be doped with an n-type and/or p-type impurity.

Then, a light emitting layer will be explained. For achieving a light emitting element by band end light emission, the amount of impurities contained in the light emitting layer must be suppressed low. Specifically, the concentration of any element of Si, Ge and group II elements is preferably 10¹⁷ cm⁻³ or less. The light emitting color of band end light emission is determined by the composition of group III elements of the light emitting layer. The light emitting layer may have either a single quantum well structure or a multiple quantum well structure. The thickness of the light emitting layer is preferably not less than 5 Å and not more than 300 Å, more preferably not less than 10 Å and not more than 90 Å. A light emitting element using a compound semiconductor with the thickness of less than 5 Å or more than 300 Å is not preferable because of insufficient light emission efficiency.

For effectively coupling charges injected into the light emitting layer, the so-called double hetero structure can be preferably used in which the light emitting layer is interposed between layers having a larger band gap than that. Hereinafter, a layer contacting with the light emitting layer and having a larger band gap than the light emitting layer is referred to as a charge injection layer in some cases. The difference in band gap between the charge injection layer and the light emitting layer is preferably 0.1 eV or more. When the difference in band gap between the charge injection layer and the light emitting layer is less than 0.1 eV, the light emission efficiency decreases because of insufficient trapping of carriers in the light emitting layer. It is more preferably 0.3 eV or more. However, since a necessary voltage to inject charges becomes higher if the band gap of the charge injection layer exceeds 5 eV, the band gap of the charge injection layer is preferably 5 eV or less. The thickness of the charge injection layer is, preferably not less than 5 Å and not more than 5,000 Å. The thickness of the charge injection layer of less than 5 Å or more than 5000 Å is not preferable because of the decrease of a high light emission efficiency, and more preferably not less than 10 Å and not more than 2,000 Å.

### Examples

Hereinafter, the present invention will be illustrated in more detail by way of examples and comparative examples, but should not be limited to the examples below.

### Example 1

Sapphire the C plane of which was polished to a mirror surface was used as the substrate. As the vapor phase growth method, MOVPE and MBE were employed. MBE is appropriately employed in manufacturing nitrides such as GaN by use of an apparatus shown in FIG. 2. First, a GaN template was made by MOVPE employing a two-stage epitaxy using GaN as a low-temperature growth buffer layer. At one atmospheric pressure, the susceptor temperature was raised to 1,100° C., the surface of the substrate was subjected to thermal cleaning in a hydrogen stream. Subsequently, hydrogen as a carrier gas, ammonia as a nitrogen raw material and trimethylgallium (hereinafter abbreviated as TMG in some cases) as a Ga raw material were supplied in 60 slm, 40 slm and 9.6 sccm, respectively, at a susceptor temperature of 485° C., to grow a GaN buffer layer of approximately 500 Å in thickness in a growth time of 5 minutes. Then, after the susceptor temperature was raised to 1,040° C., the carrier gas, ammonia and TMG were supplied in 60 slm, 40 slm and 40 sccm, respectively, to grow GaN of approximately 3 μm in thickness in a growth time of 90 minutes. Here, slm and sccm are units of gas flow amount: 1 slm denotes that a gas of a weight occupying a volume of 1 L under the standard conditions flows per 1 minute; and 1,000 sccm corresponds to 1 slm.

Next, a fluorescent substance film was grown by MBE. A GaN template made by MOVPE was introduced into an MBE apparatus, and at a temperature of 700° C., Ca, Ga and Eu were supplied to form a CaₐGa_{b}N_{c} thin film containing Eu with a thickness of 400 nm. Here, in terms of the temperature of a starting material cell, it was 400° C. for Ca, 950° C. for Ga, and 500° C. for Eu. Ammonia partial pressure was 2.6×10⁻³ Pa.

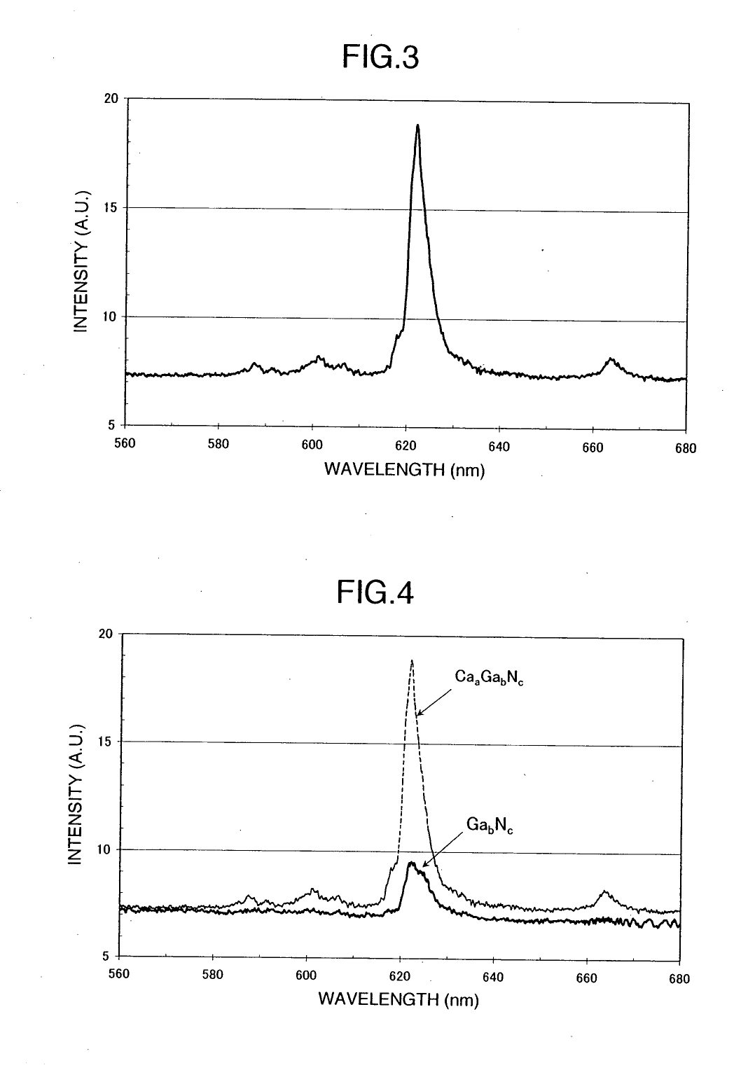

When a light emitting property of the thus obtained thin film was measured with a light of 400 nm as excitation source using a fluorescence spectrometer, red light emission of f-f transition attributable to Eu³⁺ was obtained, as shown in FIG. 3.

### Comparative Example 1

A similar fluorescent substance film was grown in the same manner as in Example 1 except that Ca was not contained on a GaN template template made by MOVPE.

When the light emitting property was measured in the same manner, the light emitting brightness was low compared with the fluorescent substance film of Example 1 containing Ca, as shown in FIG. 4.

### Example 2

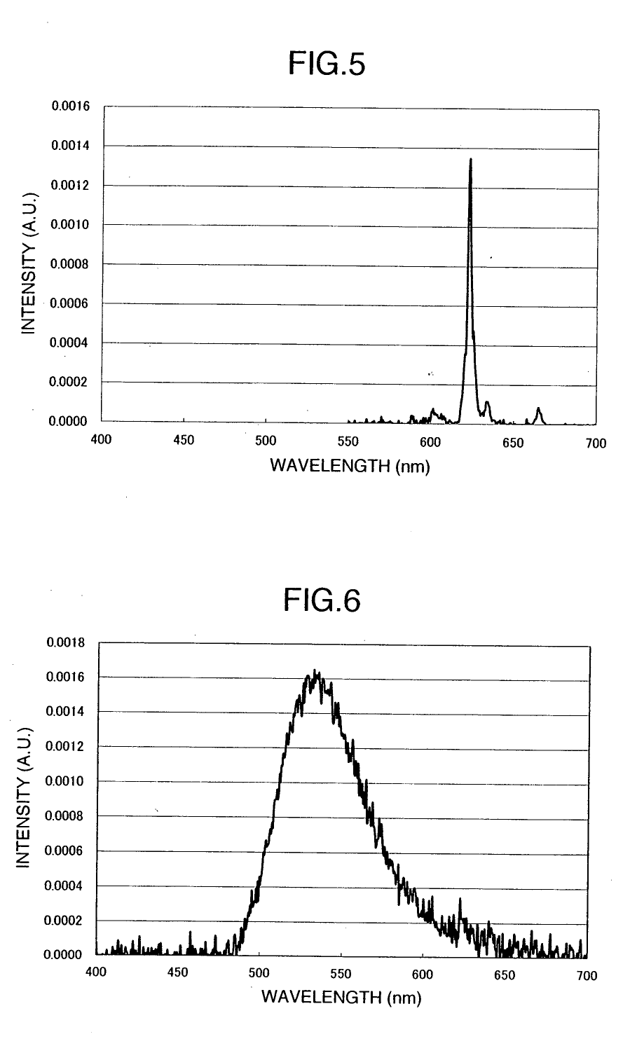

Sapphire the C plane of which was polished to a mirror surface was used as the substrate. As the vapor phase growth method, MBE was employed. The epitaxy method employed was a two-stage epitaxy using GaN as a low-temperature growth buffer layer. First, the sapphire substrate temperature was raised to about 900° C., and then the substrate was subjected to thermal cleaning. Subsequently, the substrate temperature was lowered to about 500° C. After the surface of the sapphire substrate was nitrided by applying ammonia, about 20 nm of a low-temperature GaN buffer layer was laminated at the same temperature. Then, the substrate temperature was raised to 700° C., and Ga and Eu were supplied to form a GaN thin film containing Eu with a thickness of 800 nm. Here, in terms of the temperature of a starting material cell, it was 950° C. for Ga, and 500° C. for Eu. Ammonia partial pressure was 2.6×10⁻³ Pa. When a light emitting property of the thus obtained thin film was measured with an InGaN laser of 400 nm as excitation source, red light emission of f-f transition attributable to Eu³⁺ was obtained, as shown in FIG. 5. Ca was implanted into the thin film by an ion implantation method. When volume conversion was performed at an acceleration energy of 200 keV and a dose amount of about 2×10¹⁵ Ca/cm², the density of the implanted Ca was about 1.2×10²⁰ cm⁻³. After the ion implantation, activation annealing was conducted at 1,200° C. for 1 hour in an ammonia gas stream.

When a light emitting property of the obtained thin film was similarly measured, a green broad d-f transition light emission having a peak wavelength of 530 nm was observed, as shown in FIG. 6, which seems to suggest that the Ca site was replaced with Eu²⁺.

### Example 3

Sapphire the C plane of which was polished to a mirror surface was used as the substrate. As the vapor phase growth method, the ordinary pressure MOVPE was employed. First, at one atmospheric pressure, the susceptor temperature was raised to 1,100° C., the surface of the substrate was subjected to thermal cleaning in a hydrogen stream. Subsequently, the temperature was lowered to 650° C., nitrogen as a carrier gas, ammonia as a nitrogen raw material, diethylzinc ((C₂H₅)₂Zn) as a Zn raw material, tetramethylgermanium ((CH₃)₄Ge) as a Ge raw material and bis(ethylcyclopentadienyl)manganese ((C₅H₄C₂H₅)₂Mn) as a Mn raw material were supplied in 40 slm, 7.5 slm, 10 sccm, 714 sccm and 1,000 sccm, respectively, to form ZnGeN₂ with a thickness of about 3,000 Å and Mn activated in a growth time of 30 minutes. Thereafter, the reaction furnace was cooled to room temperature still with nitrogen used as the carrier gas, and the substrate was taken out from the reaction furnace.

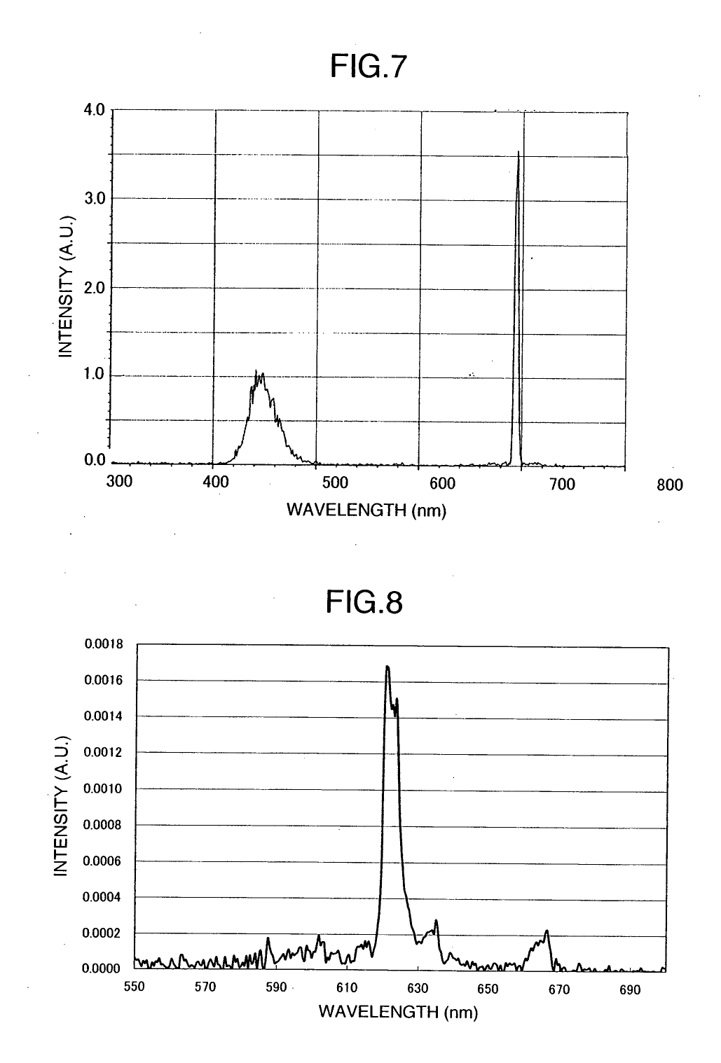

The evaluation of the taken-out substrate was performed by cathode luminescense of electron excitation. A spectrum obtained by irradiating a carbon-coated sample with an electron beam of an acceleration voltage of 15 keV is shown in FIG. 7. Blue light emission of 450 nm and red light emission of 690 nm were observed.

### Example 4

In a globe box filled with argon gas, 0.22 g of Ca, 0.3 8 g of Ga, 0.40 g of Ge, 0.008 g of Eu, and 0.07 g of Bi powder were added to a pot made of boron nitride (BN). This pot was introduced into a reactor made of quartz and heated at about 925° C. for 4 hours in an ammonia gas stream. After cooling to room temperature, the obtained lump was crushed by an agate mortar in the globe box and then pelletized into a cylindrical form using a press molding machine. The resulting pellets were heated at 925° C. for 3 hours in an ammonia stream in the same manner.

When a light emitting property of the thus obtained pellets was measured with an InGaN laser of 400 nm as excitation source, red light emission as shown in FIG. 8 was observed.

1. A fluorescent substance characterized by comprising a base crystal composed of a compound represented by the formula: M¹ₐM²_{b}N_{c} wherein M¹ is at least one element selected from the group consisting of Mg, Ca, Sr, Ba and Zn; M² is at least one element selected from the group consisting of Al, Ga and In; and c=(2a/3)+b, 0<a and 0<b, with at least one element selected from the group consisting of a rare earth metal, Zn and Mn as an activator contained therein.

2. A fluorescent substance characterized by comprising a base crystal composed of a compound represented by the formula: M³_{d}M⁴ₑN_{f}, wherein M³ is at least one element selected from the group consisting of Mg, Ca, Sr, Ba and Zn; M⁴ is at least one element selected from the group consisting of Ge, Sn and Pb; and f=(2d/3)+4e/3), 0<d and 0<e, with at least one element selected from the group consisting of a rare earth metal, Zn and Mn as an activator contained therein.

3. A fluorescent substance characterized by comprising a base crystal composed of a compound represented by the formula: M⁵_{g}M⁶ₕM⁷ⱼNₖ, wherein M⁵ is at least one element selected from the group consisting of Mg, Ca, Sr, Ba and Zn; M⁶ is at least one element selected from the group consisting of Al, Ga and In; M⁷ is at least one element selected from the group consisting of Ge, Sn and Pb; and k=(2g/3)+h+(4j/3), 0<g, 0<h and 0<j, with at least one element selected from the group consisting of a rare earth metal, Zn and Mn as an activator contained therein.

4. The fluorescent substance according to any one of claims 1 to 3, wherein the fluorescent substance has a peak of an excitation spectrum of between 390 nm to 480 nm.

5. The fluorescent substance according to claim 4, wherein the fluorescent substance has a peak of an excitation spectrum of between 390 nm to 420 nm.

6. A method of manufacturing the fluorescent substance according to any one of claims 1 to 3, characterized in that the fluorescent substance is manufactured by metal organic vapor phase epitaxy.

7. A method of manufacturing the fluorescent substance according to any one of claims 1 to 3, characterized in that the fluorescent substance is manufactured by molecular beam epitaxy.

8. A white light emitting device comprising a nitride semiconductor, characterized in that the white light emitting device comprises an LED which emits light of near ultraviolet to blue wavelength and is composed of the nitride semiconductor, and the fluorescent substance according to claim 4.

9. A white light emitting device comprising a nitride semiconductor, characterized in that the white light emitting device comprises an LED which emits light of near ultraviolet to violet wavelength and is composed of the nitride semiconductor, and the fluorescent substance according to claim 5.
